(19) United States
(12) Patent Application Publication
(10) Pub. No.: US 2014/0054665 A1
(43) Pub. Date: Feb. 27, 2014

(54) NON-VOLATILE MEMORY DEVICE AND METHOD OF MANUFACTURING THE SAME

(71) Applicant: SK HYNIX INC., Icheon-si (KR)

(72) Inventor: Noh Yeal KWAK, Icheon-si (KR)

(73) Assignee: SK HYNIX INC., Icheon-si (KR)

(21) Appl. No.: 13/713,924

(22) Filed: Dec. 13, 2012

(30) Foreign Application Priority Data
Aug. 24, 2012 (KR) 10-2012-0093123

(51) Int. Cl. H01L 29/788; H01L 29/66

(52) U.S. Cl. CPC H01L 29/788; H01L 29/66825
USPC 257/314; 438/296

(57) ABSTRACT

A non-volatile memory device includes a tunnel insulating layer formed on an active region defined by an isolation layer, a polysilicon pattern including a first portion formed on the tunnel insulating layer on the active region and a second portion protruding from the first portion beyond the isolation layer, wherein the second portion has a narrower width than the first portion, and a doped region formed near a surface of the polysilicon pattern and including p-type dopants.

### CROSS-REFERENCE TO RELATED APPLICATION

The present application claims priority to Korean patent application number 10-2012-0093123 filed on Aug. 24, 2012, in the Korean Intellectual Property Office, the entire disclosure of which is incorporated by reference herein.

### BACKGROUND

1. Technical Field

Various embodiments relate generally to a non-volatile memory device and a method of manufacturing the same and, more particularly, to a NAND flash memory device and a method of manufacturing the same.

2. Related Art

A NAND flash memory device includes a plurality of memory cells. Each of the memory cells may have a gate structure in which a tunnel insulating layer, a floating gate, a dielectric layer and a control gate are stacked. Floating gates of these memory cells may be formed on top of active regions that are separated from each other with isolation layers interposed therebetween. In general, polysilicon is widely used as materials to form floating gates. In particular, doped polysilicon may be used as materials to form floating gates in order to improve electrical characteristics of the floating gates. A control gate may extend in a direction crossing the active regions, and may be formed over the isolation layers and fill spaces between neighboring floating gates.

Dopants near the surface of a floating gate formed of doped polysilicon may diffuse out during a thermal process, thereby lowering the concentration of dopants at the surface of the floating gate. When memory cell size is reduced to achieve a higher integration density, the size of the floating gate may accordingly be reduced. Therefore, a reduction in the concentration of the dopants near the surface of the floating gate may lead to severe deterioration of cell characteristics. In addition, since the concentration of the dopants diffusing out varies depending on floating gates, program speeds may differ from cells due to differences in dopant concentrations among multiple floating gates.

When memory cell size is reduced, space between neighboring floating gates may be reduced. If a dielectric layer is formed over floating gates with space therebetween, the dielectric layer may protrude at top corners of the floating gates, covering the space between the floating gates. Since the control gate formed on top of the dielectric layer may not be formed between the floating gates, inter-cell interference may increase.

### BRIEF SUMMARY

Embodiments of the present invention relate to a non-volatile memory device with improved cell characteristics and a method of operating the same.

A non-volatile memory device according to an embodiment of the present invention includes a tunnel insulating layer formed on an active region defined by an isolation layer, a polysilicon pattern including a first portion formed on the tunnel insulating layer on the active region and a second portion protruding from the first portion beyond the isolation layer, wherein the second portion has a narrower width than the first portion, and a doped region formed near a surface of the polysilicon pattern and including p-type dopants.

A method of manufacturing a non-volatile memory device according to an embodiment of the present invention includes: forming a first polysilicon pattern on an active region of a substrate defined by an isolation layer, forming a doped region near a surface of the first polysilicon pattern by doping the surface of the first polysilicon pattern exposed above the isolation layer with p-type dopants using a plasma method, and forming a second polysilicon pattern by removing a natural oxide layer formed due to oxygen absorbed by the p-type dopants near a surface of the doped region.

### BRIEF DESCRIPTION OF THE DRAWINGS

FIGS. 1A to 1E are cross-sectional views illustrating a method of manufacturing a non-volatile memory device according to an embodiment of the present invention;

FIG. 2 is a block diagram showing the configuration of a memory system according to an embodiment of the present invention; and

FIG. 3 is a block diagram showing the configuration of a computing system according to an embodiment of the present invention.

### DETAILED DESCRIPTION

Hereinafter, various embodiments of the present disclosure will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

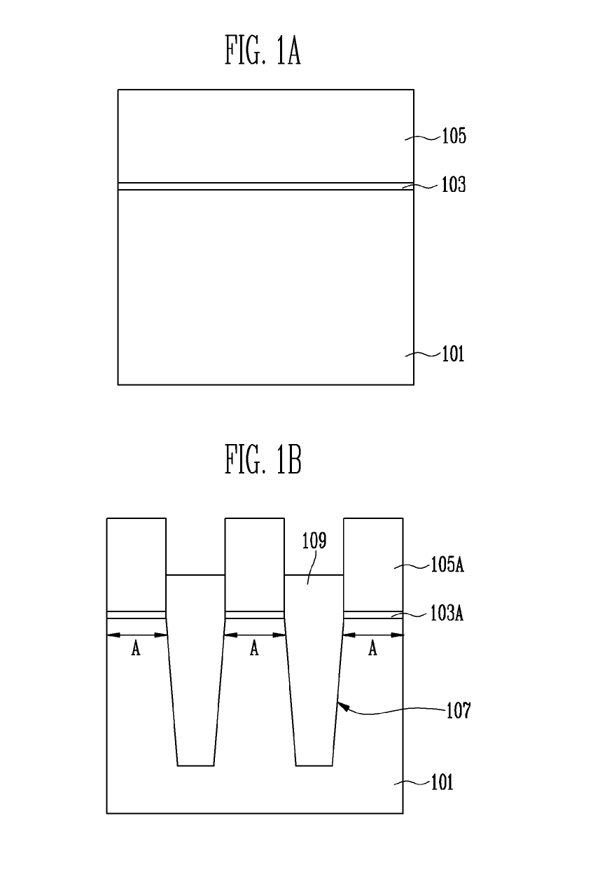

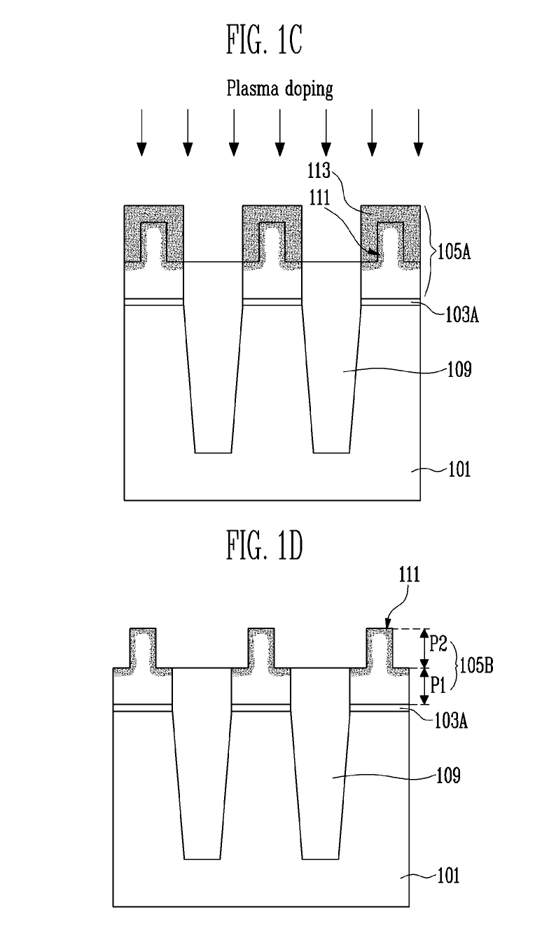

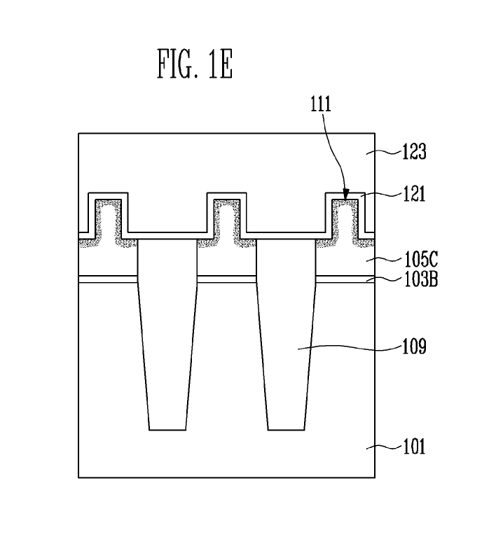

FIGS. 1A to 1E are cross-sectional views illustrating a method of manufacturing a non-volatile memory device according to an embodiment of the present invention.

Referring to FIG. 1A, a tunnel insulating layer 103 allowing electron tunneling and a polysilicon layer 105 configured as floating gates may be formed over a semiconductor substrate 101. Dopants may be implanted into the semiconductor substrate 101 to form a Triple N-well (TN well) (not illustrated) and a P well (not illustrated). The tunnel insulating layer 103 may include a silicon oxide layer. The polysilicon layer 105 may include a single doped polysilicon layer, a single undoped polysilicon layer, or a stacked layer of the undoped polysilicon layer and the doped polysilicon layer. When the polysilicon layer 105 includes a doped polysilicon layer, the doped polysilicon layer may be doped with the same p-type dopants used in subsequent processes.

Referring to FIG. 1B, first polysilicon patterns 105A may be formed over active regions A of the semiconductor substrate 101, and isolation layers 109 define the active regions A. Hereinafter, an example of processes of manufacturing the first polysilicon patterns 105A and the isolation layers 109 is described below.

First, an isolation mask (not illustrated) may be formed over the polysilicon layer 105. Subsequently, the polysilicon layer 105 may be etched by an etch process using the isolation mask as an etch barrier to form the first polysilicon patterns 105A and expose the tunnel insulating layer 103. Exposed regions of the tunnel insulating layer 103 may be etched to form tunnel insulating layer patterns 103A and expose the semiconductor substrate 101. Exposed regions of the semiconductor substrate 101 may be etched by a predetermined depth to form isolation trenches 107. As a result, the active regions A may be defined in regions where the isolation trenches 107 are not formed.

Subsequently, an insulating layer may be formed over a resultant structure in which the isolation mask, the first polysilicon patterns 105A, the tunnel insulating layer patterns 103A and the isolation trenches 107 were formed. The insulating layer may fill the isolation trenches 107 and spaces between the first polysilicon patterns 105A. The insulating layer may be formed in such a manner that a polysilazane (PSZ) layer having gap-fill characteristics is coated on the resultant structure and then cured by an annealing process. During the annealing process, dopants in the first polysilicon patterns 105A may diffuse out.

Subsequently, the insulating layer formed over the isolation mask may be removed, and the height of the insulating layer formed in the isolation trenches 107 may be reduced by using an etch process performed to control the effective field height (EFH) of the insulating layer. As a result, the isolation layers 109 with the controlled EFH may be formed. The isolation layers 109 may be formed in the isolation trenches 107 with a higher surface level than that of the tunnel insulating layer pattern 103A and a lower surface level than that of the first polysilicon pattern 105A. As a result, portions of sidewalls of the first polysilicon patterns 105A may be exposed. The isolation mask may be removed by a separate etch process, or may be removed during the etch process of the insulating layer.

Referring to FIG. 1C, surfaces of the first polysilicon patterns 105A exposed above the isolation layers 109 may be doped with dopants using a plasma doping method. P-type dopants such as Boron may be used that allow for easy absorption of oxygen. As a result, p-type doped regions 111 may be formed near the surfaces of the first polysilicon patterns 105A.

By using the plasma doping method, since the dopants are introduced by controlling a bias in a plasma atmosphere, the damage to the first polysilicon patterns 105A may be slight when compared to an ion beam implantation method by which dopants are introduced by accelerating ion beams.

Using the above-described plasma doping method, the exposed surfaces of the polysilicon patterns 105A may be uniformly doped with dopants with a target thickness by controlling plasma density and bias. Therefore, by using the plasma doping method, it is possible to have lower dopant concentrations at a lower portion of the first polysilicon pattern 105A adjacent to the tunnel insulating layer pattern 103A and higher dopant concentrations at an upper portion of the first polysilicon pattern 105A adjacent to the upper surface of the first polysilicon pattern 105A.

As a result, the dopant concentration in the first polysilicon patterns 105A may increase to improve electrical characteristics thereof, while reducing the amount of dopants moving into the tunnel insulating layer patterns 103A, thereby maintaining a low dopant concentration in the lower portions of the first polysilicon patterns 105A adjacent to the tunnel insulating layer patterns 103A. In comparison to an in-situ method in which doped regions are formed over the entire internal areas of the first polysilicon patterns 105A, the plasma doping method that can limit the doped regions 111 to the surfaces of the first polysilicon patterns 105A improve characteristics of the tunnel insulating layer patterns 103A.

Each of the doped regions 111 formed by the plasma doping method may be formed at a uniform doping concentration on a corresponding one of the first polysilicon patterns 105A. According to an embodiment of the present invention, since uniformity of doping concentrations in the first polysilicon patterns 105A is achieved, uniformity of program speeds according to each cell may be improved.

Since the exposed surfaces of the first polysilicon patterns 105A, especially surfaces of the doped regions 111 are doped with p-type dopants, oxygen may be likely to be absorbed into the p-type dopants. When oxygen are absorbed into the p-type dopants, the surfaces of the doped regions 111 may be oxidized to a predetermined thickness, thereby forming natural oxide layers 113. Each natural oxide layer 113 is a product of oxygen, generated in a chamber during a plasma doping process or oxygen present outside the chamber with the substrate 101 exposed to the outside, reacting with the p-type dopants of the doped region 111.

The thickness of the natural oxide layer 113 may be controlled by adjusting a partial pressure ratio between a source gas and an inert gas. The source gas may include p-type dopants such as B₂H₆. The inert gas may reduce the oxidation rate, and thus slow down the formation of the natural oxide layers 113. For example, the inert gas may include at least one of Ar, N₂ and H₂. The natural oxide layer 113 may have a smaller thickness than the doped region 111 so as not to remove the doped region 111.

Referring to FIG. 1D, the natural oxide layers 113 may be removed to form second polysilicon patterns 105B. Each second polysilicon pattern 105B may have an upper width narrower than a lower width. In general, the natural oxide layer 113 may be removed by a cleaning process so as to not require a separate process of removing the natural oxide layers 113.

Each second polysilicon pattern 105B may include a first portion P1 and a second portion P2. Since the first portion P1 is protected by the isolation layer 109, the first portion P1 may not be oxidized and has a first width. The second portion P2 may protrude from the first portion P1 beyond the isolation layers 109 and have a second width narrower than the first width. According to an embodiment of the present invention, the second width of the second polysilicon pattern 105B may be determined by controlling the thickness of the natural oxide layer 113 formed without a separate oxidation process.

Since the doped region 111 remains at surfaces of the second portion P2 and the first portion P1 of the second polysilicon pattern 105B, doping concentrations of the p-type dopants may be greater at the surface of the first and second portions P1 and P2 and the surface of the first portion P1 than in central portions of the first and second portions P1 and P2.

Referring to FIG. 1E, a dielectric layer may be formed along the surfaces of the second polysilicon patterns 105B, and a control gate layer may be formed over the dielectric layer. Subsequently, a gate mask (not illustrated) may be formed over the control gate layer in the direction crossing the active regions A. By performing a gate patterning process using the gate mask as an etch barrier, the dielectric layer, the control gate layer and the second polysilicon patterns 105B may be etched to form a control gate pattern 123, a dielectric layer pattern 121 and third polysilicon patterns 105C. The third polysilicon patterns 105C may become floating gates of the NAND flash memory device. The tunnel insulating layer patterns 103A may be further etched during the gate patterning process so that the final tunnel insulating layer patterns 103B may remain under the third polysilicon patterns 105C.

The above-described dielectric layer may be formed over surfaces of the second portions P2 having a narrower width than the first portions P1 of the second polysilicon patterns 105B. Since spaces between the second portions P2 are larger than spaces between the first portions P1, the spaces between the second portions P2 may be open even when the dielectric layer is formed. Therefore, the control gate layer may fill space between the second portions P2, thereby reducing inter-cell interference.

According to an embodiment of the present invention, inter-cell interference may be reduced, and electrical characteristics of the third polysilicon patterns 105C may be ensured by forming the doped regions 111 in the third polysilicon patterns 105C configured as floating gates, so that cell characteristics may be improved.

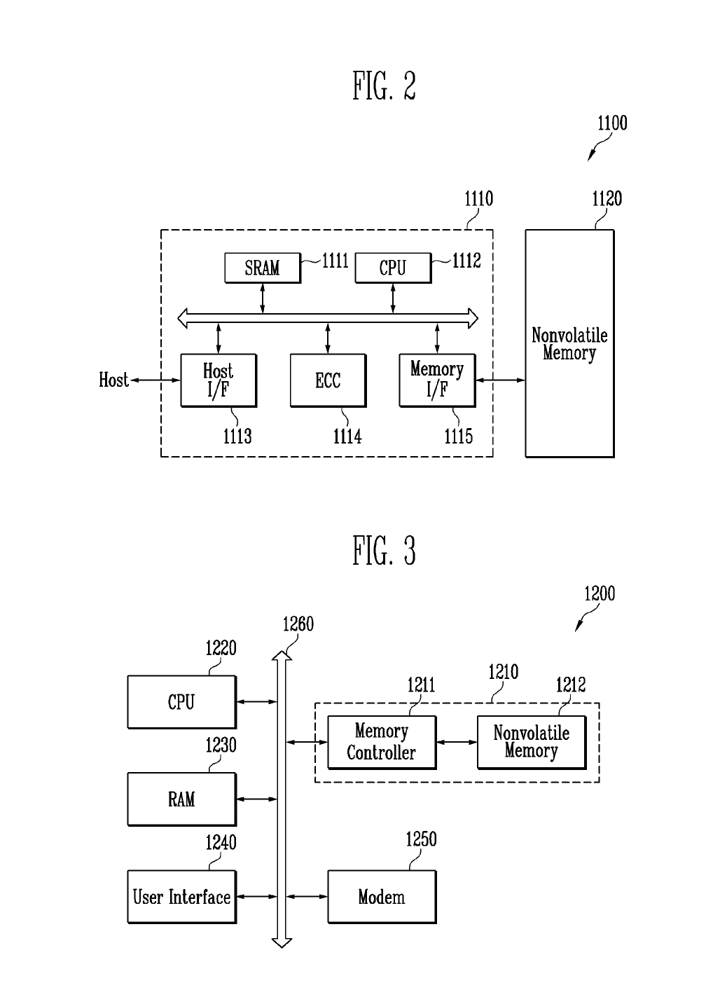

FIG. 2 is a view illustrating the configuration of a memory system according to another embodiment of the present invention.

As illustrated in FIG. 2, a memory system 1100 according to an embodiment of the present invention may include a non-volatile memory device 1120 and a memory controller 1110.

The non-volatile memory device 1120 may include the non-volatile memory device described with reference to the above-described embodiments in connection with FIGS. 1A to 1E. In addition, the non-volatile memory device 1120 may be a multi-chip package composed of a plurality of flash memory chips.

The memory controller 1110 may be configured to control the non-volatile memory device 1120. The memory controller 1110 may include an SRAM 1111, a CPU 1112, a host interface 1113, an ECC 1114 and a memory interface 1115. The SRAM 1111 may function as an operation memory of the CPU 1112. The CPU 1112 may perform a general control operation for data exchange of the memory controller 1110. The host interface 1113 may include a data exchange protocol of a host being coupled to the memory system 1100. In addition, the ECC 1114 may detect and correct errors included in a data read from the non-volatile memory device 1120. The memory interface 1115 may interface with the non-volatile memory device 1120. The memory controller 1110 may further include a ROM that stores code data to interface with the host.

The memory system 1100 having the above-described configuration may be a solid state disk (SSD) or a memory card in which the memory device 1120 and the memory controller 1110 are combined. For example, when the memory system 1100 is an SSD, the memory controller 1110 may communicate with the outside (e.g., a host) through one of the interface protocols including USB, MMC, PCI-E, SATA, PATA, SCSI, ESDI and IDE.

FIG. 3 is a view illustrating the configuration of a computing system according to an embodiment of the present invention.

As illustrated in FIG. 3, a computing system 1200 according to an embodiment of the present invention may include a CPU 1220, RAM 1230, a user interface 1240, a modem 1250 and a memory system 1210 that are electrically coupled to a system bus 1260. In addition, when the computing system 1200 is a mobile device, a battery may be further included to apply an operating voltage to the computing system 1200. The computing system 1200 may further include application chipsets, a Camera Image Processor (CIS) and a mobile DRAM.

As described above with reference to FIG. 2, the memory system 1210 may include a non-volatile memory 1212 and a memory controller 1211.

According to an embodiment of the present invention, a natural oxide layer is formed at a surface of a polysilicon pattern, and the width of the polysilicon pattern may be reduced by removing the natural oxide layer, so that a large space may be ensured between neighboring polysilicon patterns. Therefore, since the space between the polysilicon patterns may not be covered by a dielectric layer in a subsequent process of forming the dielectric layer, a control gate layer may be subsequently formed between the polysilicon patterns in the following process of forming the control gate layer. Accordingly, inter-cell interference may be reduced.

In addition, the amount of dopants in a polysilicon pattern may be supplemented by doping the polysilicon pattern with dopants by using a plasma method.

What is claimed is:

1. A non-volatile memory device, comprising:
a tunnel insulating layer formed on an active region defined by an isolation layer;
a polysilicon pattern including a first portion formed on the tunnel insulating layer on the active region and a second portion protruding from the first portion beyond the isolation layer, wherein the second portion has a narrower width than the first portion; and
a doped region formed near a surface of the polysilicon pattern and including p-type dopants.

2. The non-volatile memory device of claim 1, wherein the polysilicon pattern includes p-type dopants.

3. The non-volatile memory device of claim 2, wherein a concentration of the p-type dopants included in the polysilicon pattern is greater on surfaces of the first and second portions than in central portions of the first and second portions.

4. A method of manufacturing a non-volatile memory device, the method comprising:
forming a first polysilicon pattern on an active region of a substrate defined by an isolation layer;
forming a doped region near a surface of the first polysilicon pattern by doping the surface of the first polysilicon pattern exposed above the isolation layer with p-type dopants by using a plasma method; and
forming a second polysilicon pattern by removing a natural oxide layer formed due to oxygen absorbed by the p-type dopants near a surface of the doped region.

5. The method of claim 4, wherein in the formation of the doping region by using the plasma method, a thickness of the natural oxide layer is controlled by adjusting a partial pressure of a source gas including the p-type dopants and a partial pressure of an inert gas, thereby reducing a rate at which the natural oxide layer is formed.

6. The method of claim 4, wherein the source gas includes B₂H₆, and the inert gas includes at least one of Ar, N₂ and H₂.

7. The method of claim 4, wherein a thickness of the natural oxide layer is smaller than a thickness of the doped region.

8. The method of claim 4, wherein the formation of the first polysilicon pattern on the active region of the substrate defined by the isolation layer comprises:
forming a tunnel insulating layer and a polysilicon layer over the substrate;
forming the first polysilicon pattern by etching the polysilicon layer and the tunnel insulating layer to expose the substrate;
forming a trench by etching an exposed region of the substrate;
filling the trench with an insulating layer; and
forming the isolation layer by etching the insulating layer so that the insulating layer is formed at a lower position than the first polysilicon pattern.

9. The method of claim 8, wherein the polysilicon layer is a doped polysilicon layer including p-type dopants.

10. The method of claim 8, wherein the tunnel insulating layer includes a silicon oxide layer.
